(19) United States
(12) Patent Application Publication
(10) Pub. No.: US 2022/0417632 A1
(43) Pub. Date: Dec. 29, 2022

(54) MEMS MICROPHONE AND METHOD OF MANUFACTURING THE SAME

(71) Applicant: DB HITEK CO., LTD., Seoul (KR)

(72) Inventor: Myeong Hwan LIM, Jeollabuk-do (KR)

(21) Appl. No.: 17/809,456

(22) Filed: Jun. 28, 2022

(30) Foreign Application Priority Data
Jun. 29, 2021 (KR) 10-2021-0084894

(51) Int. Cl. H04R 1/08; H04R 31/00; B81C 1/00; H04R 7/12

(52) U.S. Cl. CPC H04R 1/08; H04R 31/003; B81C 1/00182; H04R 7/12; H04R 2201/003

(57) ABSTRACT

A MEMS microphone includes a substrate having a cavity, a diaphragm disposed above the substrate to correspond to the cavity, and a back plate disposed above the diaphragm. The diaphragm includes a concave-convex structure, and the back plate includes a second concave-convex structure corresponding to the concave-convex structure.

### CROSS-REFERENCE TO RELATED APPLICATION

This application claims the priority benefit of Korean Patent Application No. 10-2021-0084894, filed on Jun. 29, 2021, and all the benefits accruing therefrom under 35 U.S.C. § 119, the contents of which are incorporated by reference in their entirety.

### TECHNICAL FIELD

The present disclosure relates to a MEMS (Micro-Electro Mechanical System) microphone and a method of manufacturing the same. More specifically, the present disclosure relates to a MEMS microphone capable of converting a sound into an acoustic signal using a diaphragm configured to be vibrated by a sound pressure and a method of manufacturing the same.

### BACKGROUND

A MEMS microphone may be used to convert a sound into an acoustic signal and may be manufactured by a MEMS technology. For example, the MEMS microphone may include a diaphragm disposed above a substrate and a back plate disposed above the diaphragm. The diaphragm and the back plate may be supported by a plurality of anchors on the substrate and a predetermined air gap may be provided between the diaphragm and the back plate.

The diaphragm may include a lower conductive layer used as a lower electrode, and the back plate may include an upper conductive layer used as an upper electrode, and an insulating layer formed on the upper conductive layer to support the upper conductive layer. The diaphragm may be vibrated by an applied sound pressure, whereby the air gap between the diaphragm and the back plate may be changed. Further, a capacitance between the diaphragm and the back plate may be changed by the change in the air gap and the acoustic signal may be detected from the change in the capacitance.

The capacitance may be proportional to areas of the lower electrode and the upper electrode and may be inversely proportional to a distance between the lower electrode and the upper electrode, that is, the air gap. Accordingly, it is preferable to increase the areas of the lower electrode and the upper electrode in order to improve the sensitivity of the MEMS microphone. However, when the size of the MEMS microphone is reduced, there is a limit to increasing the areas of the lower electrode and the upper electrode.

### SUMMARY

The present disclosure provides a MEMS microphone with increased capacitance and a method of manufacturing the same.

In accordance with an aspect of the present disclosure, a MEMS microphone may include a substrate having a cavity, a diaphragm disposed above the substrate to correspond to the cavity, and a back plate disposed above the diaphragm. Particularly, the diaphragm may include a concave-convex structure.

In accordance with some embodiments of the present disclosure, the diaphragm may include a lower electrode layer made of a conductive material and having the concave-convex structure, and the back plate may include a support layer made of an insulating material and an upper electrode layer attached to a lower surface of the support layer and made of a conductive material.

In accordance with some embodiments of the present disclosure, the concave-convex structure may include convex portions protruding downward.

In accordance with some embodiments of the present disclosure, each of the convex portions may have a shape of a hollow pyramid, a hollow truncated pyramid, a hollow cone, or a hollow truncated cone.

In accordance with some embodiments of the present disclosure, the diaphragm may further include a first anchor portion configured to surround the lower electrode layer and to fix the lower electrode layer on the substrate, and the back plate may further include a second anchor portion configured to fix the support layer on the substrate.

In accordance with some embodiments of the present disclosure, the support layer may include protrusions penetrating through the upper electrode layer and protruding toward the lower electrode layer.

In accordance with some embodiments of the present disclosure, the back plate may include a second concave-convex structure corresponding to the concave-convex structure.

In accordance with some embodiments of the present disclosure, the concave-convex structure may include convex portions protruding downward and the second concave-convex structure may include second convex portions corresponding to the convex portions and protruding downward.

In accordance with some embodiments of the present disclosure, each of the convex portions may have an upper inclined surface and each of the second convex portions may have a lower inclined surface corresponding to the upper inclined surface.

In accordance with some embodiments of the present disclosure, each of the second convex portions may have a shape of a hollow pyramid, a hollow truncated pyramid, a hollow cone, or a hollow truncated cone.

In accordance with another aspect of the present disclosure, a method of manufacturing a MEMS microphone may include forming a diaphragm comprising a concave-convex structure above a substrate, forming a back plate above the diaphragm and forming a cavity through the substrate to expose a lower surface of the diaphragm.

In accordance with some embodiments of the present disclosure, the forming of the diaphragm may include forming a mask layer exposing surface portions of the substrate, forming concave portions by performing an etching process using the mask layer as an etching mask, removing the mask layer, forming a lower insulating layer having second concave portions on the substrate, forming a lower silicon layer having the concave-convex structure on the lower insulating layer, and forming the diaphragm by patterning the lower silicon layer.

In accordance with some embodiments of the present disclosure, the forming of the diaphragm may further include forming a portion of the lower silicon layer into a lower electrode layer by performing an ion implantation process.

In accordance with some embodiments of the present disclosure, the forming of the diaphragm may further include forming a first anchor channel partially exposing the substrate by partially removing the lower insulating layer. In such cases, a portion of the lower silicon layer formed in the first anchor channel may function as a first anchor portion for fixing the diaphragm on the substrate.

In accordance with some embodiments of the present disclosure, the forming of the back plate may include forming an upper insulating layer on the diaphragm, forming an upper silicon layer on the upper insulating layer, forming a portion of the upper silicon layer into an upper electrode layer by performing an ion implantation process, exposing a portion of the upper insulating layer by removing another portion of the upper silicon layer, and forming a support layer for supporting the upper electrode layer on the upper electrode layer and the exposed portion of the upper insulating layer.

In accordance with some embodiments of the present disclosure, the forming of the back plate may further include forming a second anchor channel partially exposing the substrate by partially removing the upper insulating layer and the lower insulating layer. In such cases, a portion of the support layer formed in the second anchor channel may function as a second anchor portion for fixing the back plate on the substrate.

In accordance with some embodiments of the present disclosure, the forming of the back plate may further include forming holes penetrating through the upper electrode layer and removing upper portions of the upper insulating layer. In such cases, the support layer may be formed to fill the holes, thereby forming protrusions penetrating the upper electrode layer and protruding toward the diaphragm.

In accordance with some embodiments of the present disclosure, the back plate may include a second concave-convex structure corresponding to the concave-convex structure.

In accordance with some embodiments of the present disclosure, the concave-convex structure may include convex portions protruding downward and the second concave-convex structure may include second convex portions corresponding to the convex portions and protruding downward.

In accordance with some embodiments of the present disclosure, each of the convex portions may have an upper inclined surface and each of the second convex portions may have a lower inclined surface corresponding to the upper inclined surface.

In accordance with the embodiments of the present disclosure as described above, the diaphragm and the back plate may include a concave-convex structure and a second concave-convex structure corresponding to each other, respectively. Accordingly, areas facing each other of the diaphragm and the back plate may be increased, and thus, the sensitivity of the MEMS microphone may be significantly improved.

The above summary of the present disclosure is not intended to describe each illustrated embodiment or every implementation of the present disclosure. The detailed description and claims that follow more particularly exemplify these embodiments.

### BRIEF DESCRIPTION OF THE DRAWINGS

Embodiments can be understood in more detail from the following description taken in conjunction with the accompanying drawings, in which:

FIG. 1 is a schematic plan view illustrating a MEMS microphone in accordance with an embodiment of the present disclosure;

FIG. 2 is a schematic cross-sectional view taken along a line I-I′ as shown in FIG. 1;

FIG. 3 is a schematic plan view illustrating a concave-convex structure of a diaphragm as shown in FIG. 2;

FIG. 4 is a schematic plan view illustrating another example of the concave-convex structure as shown in FIG. 3;

FIG. 5 is a flowchart illustrating a method of manufacturing the MEMS microphone as shown in FIGS. 1 and 2; and

FIGS. 6 to 20 are schematic cross-sectional views illustrating the method of manufacturing the MEMS microphone as shown in FIG. 5.

While various embodiments are amenable to various modifications and alternative forms, specifics thereof have been shown by way of example in the drawings and will be described in detail. It should be understood, however, that the intention is not to limit the claimed inventions to the particular embodiments described. On the contrary, the intention is to cover all modifications, equivalents, and alternatives falling within the spirit and scope of the subject matter as defined by the claims.

### DETAILED DESCRIPTION

Hereinafter, embodiments of the present invention are described in more detail with reference to the accompanying drawings. However, the present invention is not limited to the embodiments described below and is implemented in various other forms. Embodiments below are not provided to fully complete the present invention but rather are provided to fully convey the range of the present invention to those skilled in the art.

In the specification, when one component is referred to as being on or connected to another component or layer, it can be directly on or connected to the other component or layer, or an intervening component or layer may also be present. Unlike this, it will be understood that when one component is referred to as directly being on or directly connected to another component or layer, it means that no intervening component is present. Also, though terms like a first, a second, and a third are used to describe various regions and layers in various embodiments of the present invention, the regions and the layers are not limited to these terms.

Terminologies used below are used to merely describe specific embodiments, but do not limit the present invention. Additionally, unless otherwise defined here, all the terms including technical or scientific terms, may have the same meaning that is generally understood by those skilled in the art.

Embodiments of the present invention are described with reference to schematic drawings of ideal embodiments. Accordingly, changes in manufacturing methods and/or allowable errors may be expected from the forms of the drawings. Accordingly, embodiments of the present invention are not described being limited to the specific forms or areas in the drawings and include the deviations of the forms. The areas may be entirely schematic, and their forms may not describe or depict accurate forms or structures in any given area and are not intended to limit the scope of the present invention.

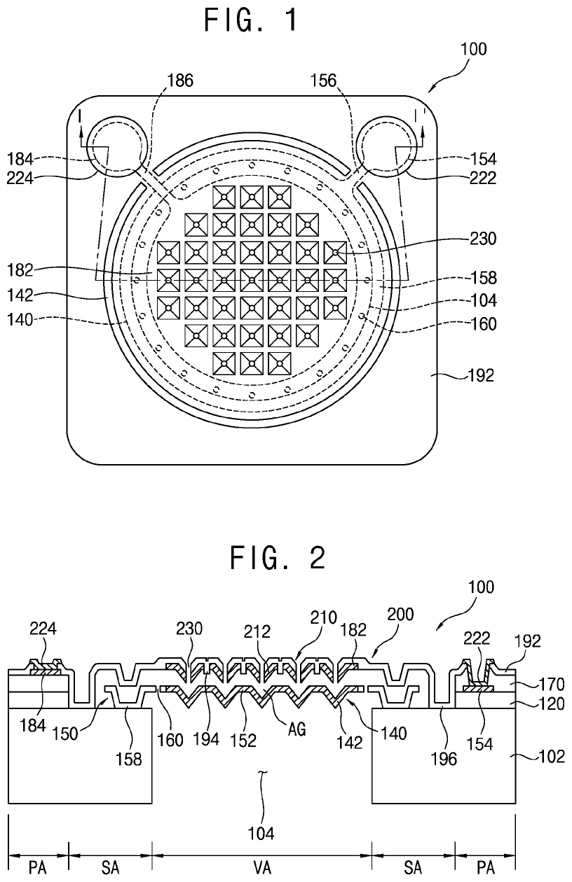

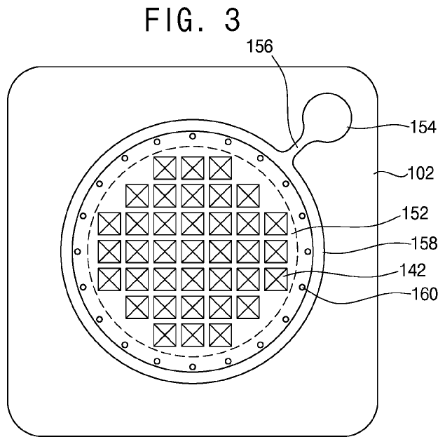

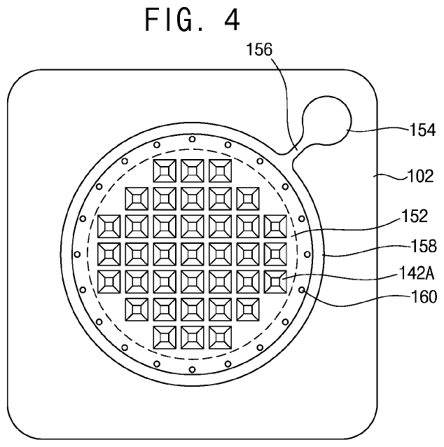

FIG. 1 is a schematic plan view illustrating a MEMS microphone in accordance with an embodiment of the present disclosure. FIG. 2 is a schematic cross-sectional view taken along a line I-I′ as shown in FIG. 1. FIG. 3 is a schematic plan view illustrating a concave-convex structure of a diaphragm as shown in FIG. 2. FIG. 4 is a schematic plan view illustrating another example of the concave-convex structure as shown in FIG. 3.

Referring to FIGS. 1 to 4, a MEMS microphone 100, in accordance with an embodiment of the present disclosure, may include a substrate 102 having a cavity 104, a diaphragm 150 disposed above the substrate 102 to correspond to the cavity 104, and a back plate 200 disposed above the diaphragm 150.

In embodiments, the substrate 102 may be a single-crystal silicon substrate and may include a vibration area (VA), a support area (SA) surrounding the vibration area (VA), and a periphery area (PA) surrounding the support area (SA). In such cases, the cavity 104 may be formed to pass through the vibration area (VA) and the diaphragm 150 may be exposed through the cavity 104.

In accordance with an embodiment of the present disclosure, the diaphragm 150 may have a concave-convex structure 140 and may be spaced apart from the substrate 102 to be vibrated by an applied sound pressure. In embodiments, the diaphragm 150 may include a lower electrode layer 152 made of a conductive material and having the concave-convex structure 140. The diaphragm 150 may include a first anchor portion 158 configured to surround the lower electrode layer 152 and the lower electrode layer 152 may be fixed on the substrate 102 by the first anchor portion 158. In embodiments, the lower electrode layer 152 may be made of polysilicon doped with impurities and the first anchor portion 158 may be made of undoped polysilicon. Further, the first anchor portion 158 may have a ring shape surrounding the lower electrode layer 152 and may be formed on the support area (SA) of the substrate 102.

The concave-convex structure 140 may include a plurality of convex portions 142 protruding downward. That is, the concave-convex structure 140 may include a plurality of convex portions 142 protruding toward the cavity 104. In embodiments, as shown in FIGS. 2 and 3, each of the convex portions 142 may have a hollow pyramid shape protruding downward. As another embodiment, as shown in FIG. 4, convex portions 142A having a hollow truncated pyramid shape protruding downward may be used. Further, alternatively, although not shown in figures, convex portions having a hollow cone shape or a hollow truncated cone shape may be used. As a result, an area of the lower electrode layer 152 may be increased by the concave-convex structure 140. Accordingly, the capacitance of the MEMS microphone 100 may be increased, and thus, the sensitivity of the MEMS microphone 100 may be improved.

Further, the diaphragm 150 may include a first electrode pad 154 electrically connected to the lower electrode layer 152. In embodiments, the first electrode pad 154 may be connected to the lower electrode layer 152 by a first connection pattern 156 as shown in FIG. 1. In this case, the first electrode pad 154 and the first connection pattern 156 may be made of the same material as the lower electrode layer 152.

The back plate 200 may include a support layer 192 made of an insulating material, and an upper electrode layer 182 attached to a lower surface of the support layer 192 and made of a conductive material. In particular, the back plate 200 may be disposed above the diaphragm 150 so that the upper electrode layer 182 is spaced apart from the lower electrode layer 152 by a predetermined distance. That is, a predetermined air gap (AG) may be provided between the lower electrode layer 152 and the upper electrode layer 182. In embodiments, the upper electrode layer 182 may be made of polysilicon doped with impurities and the support layer 192 may be made of silicon nitride.

In addition, the back plate 200 may include a second anchor portion 196 for fixing the support layer 192 on the substrate 102 and a second electrode pad 184 electrically connected to the upper electrode layer 182. In embodiments, as shown in FIG. 2, the second anchor portion 196 may be disposed on the support area (SA) of the substrate 102 and may be made of silicon nitride. The upper electrode layer 182 and the second electrode pad 184 may be electrically connected by a second connection pattern 186, as shown in FIG. 1. Further, the second electrode pad 184 and the second connection pattern 186 may be formed of the same material as the upper electrode layer 182.

The first anchor portion 158 may have a circular ring shape surrounding the cavity 104. The second anchor portion 196 may have a circular ring shape surrounding the first anchor portion 158. Further, between the lower electrode layer 152 and the first anchor portion 158, a plurality of ventilation holes 160 for connecting the air gap (AG) between the diaphragm 150 and the back plate 200 with an inner space of the cavity 104 may be formed through the diaphragm 150.

A lower insulating layer 120 may be disposed on an upper surface of the substrate 102 and an upper insulating layer 170 may be disposed on the lower insulating layer 120. In this case, the first electrode pad 154 may be disposed on the lower insulating layer 120 and the second electrode pad 184 may be disposed on the upper insulating layer 170. In embodiments, the lower insulating layer 120 and the upper insulating layer 170 may be made of silicon oxide and may be formed to surround the second anchor portion 196.

A first bonding pad 222 may be disposed on the first electrode pad 154 and a second bonding pad 224 may be disposed on the second electrode pad 184. In embodiments, as shown in FIG. 15, a first contact hole (CH1) exposing the first electrode pad 154 may be formed through the support layer 192 and the upper insulating layer 170, and the first bonding pad 222 may be formed in the first contact hole (CH1). Further, a second contact hole (CH2) exposing the second electrode pad 184 may be formed through the support layer 192 and the second bonding pad 224 may be formed in the second contact hole (CH2). In addition, the support layer 192 may include protrusions 194 penetrating through the upper electrode layer 182 and protruding toward the lower electrode layer 152. The protrusions 194 may be made of the same material as the support layer 192 and may be used to prevent the lower electrode layer 152 and the upper electrode layer 182 from contacting each other.

In accordance with an embodiment of the present disclosure, the back plate 200 may include a second concave-convex structure 210 corresponding to the concave-convex structure 140. In embodiments, the second concave-convex structure 210 may include second convex portions 212 respectively corresponding to the convex portions 142 and protruding downward, that is, toward the convex portions 142. In embodiments, each of the second convex portions 212 may have a shape of a hollow pyramid, a hollow truncated pyramid, a hollow cone, or a hollow truncated cone. In particular, each of the convex portions 142 may have an upper inclined surface, and each of the second convex portions 212 may have a lower inclined surface corresponding to the upper inclined surface. As a result, an area of the upper electrode layer 182 may be increased by the second concave-convex structure 210. Accordingly, the capacitance of the MEMS microphone 100 may be increased, and thus, the sensitivity of the MEMS microphone 100 may be improved.

In addition, the back plate 200 may have a plurality of air holes 230 connected to the air gap (AG). The air holes 230 may be formed through the support layer 192 and the upper electrode layer 182. In embodiments, the air holes 230 may be formed through the second convex portions 212 and the protrusions 194 may be disposed between the second convex portions 212.

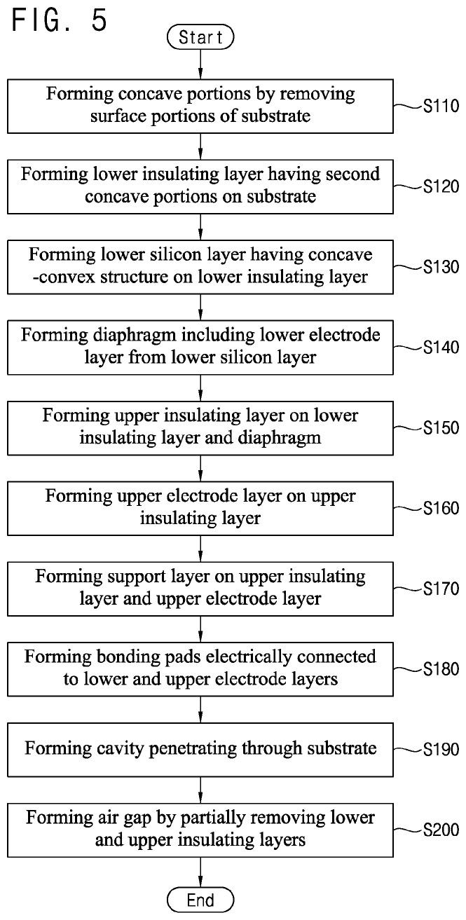

FIG. 5 is a flowchart illustrating a method of manufacturing the MEMS microphone as shown in FIGS. 1 and 2. FIGS. 6 to 20 are schematic cross-sectional views illustrating the method of manufacturing the MEMS microphone as shown in FIG. 5.

Referring to FIGS. 5 to 7, in step S110, concave portions 112 may be formed by removing surface portions of a substrate 102. Specifically, as shown in FIG. 6, a mask layer 110 exposing surface portions of a substrate 102 may be formed on the substrate 102. In embodiments, the substrate 102 may be a single crystal silicon substrate and the mask layer 110 may be formed of silicon oxide. Specifically, after a silicon oxide layer (not shown) may be formed on the substrate 102 by a thermal oxidation process or a chemical vapor deposition process, a photoresist pattern (not shown) may be formed on the silicon oxide layer. Then, the mask layer 110 may be formed from the silicon oxide layer by performing an anisotropic etching process using the photoresist pattern as an etching mask. After the mask layer 110 is formed, the photoresist pattern may be removed by a stripping process and/or an ashing process.

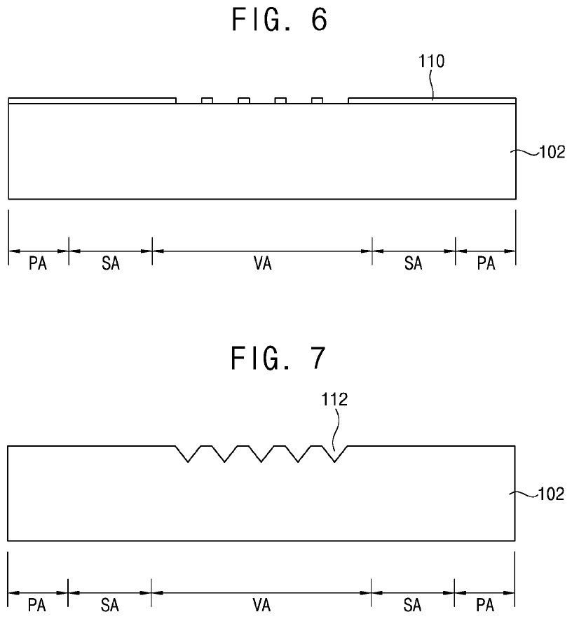

Referring to FIG. 7, an etching process using the mask layer 110 may be performed to partially remove the surface portions of the substrate 102. In embodiments, the surface portions of the substrate 102 may be removed by wet etching. A plurality of concave portions 112 may be formed in the surface portions of the substrate 102 by the wet etching. In particular, the concave portions 112 may have inclined inner surfaces due to a difference in etch rates according to crystallographic orientations of the substrate 102. In embodiments, the surface portions of the substrate 102 may be removed by a wet etching process using an aqueous solution of potassium hydroxide (KOH) as an etchant. After forming the concave portions 112, the mask layer 110 may be removed through an etching process.

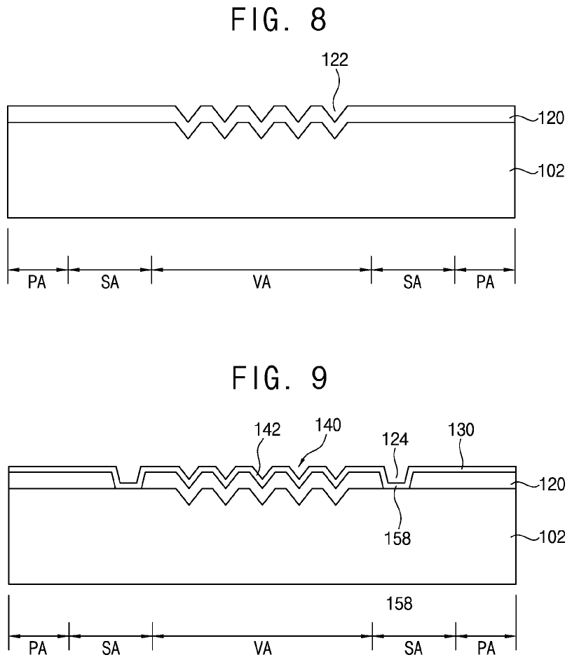

Referring to FIGS. 5 and 8, in step S120, a lower insulating layer 120 having second concave portions 122 may be formed on the substrate 102. In embodiments, the lower insulating layer 120 may include silicon oxide and may be formed conformally, that is, to have an approximately uniform thickness through a chemical vapor deposition process. As a result, the lower insulating layer 120 having the second concave portions 122 corresponding to the concave portions 112 may be formed on the substrate 102.

Referring to FIGS. 5 and 9, in step S130, a lower silicon layer 130 having a concave-convex structure 140 may be formed on the lower insulating layer 120. Specifically, the lower insulating layer 120 may be patterned to form a first anchor channel 124 having a circular ring shape to surround the concave portions 112. In embodiments, after forming a photoresist pattern exposing a portion where the first anchor channel 124 is to be formed on the lower insulating layer 120, an etching process using the photoresist pattern as an etching mask may be performed, whereby the first anchor channel 124 may be formed to expose a portion of the upper surface of the substrate 102.

After the first anchor channel 124 is formed, a lower silicon layer 130 may be conformally formed on the lower insulating layer 120 to have an approximately uniform thickness. In embodiments, the lower silicon layer 130 may be a polysilicon layer formed by a chemical vapor deposition process. In such cases, a concave-convex structure 140 including convex portions 142 protruding downward may be formed by the second concave portions 122. In addition, a portion of the lower silicon layer 130 formed in the first anchor channel 124 may be used as a first anchor portion 158 for fixing a diaphragm 150 to be formed subsequently on the substrate 102.

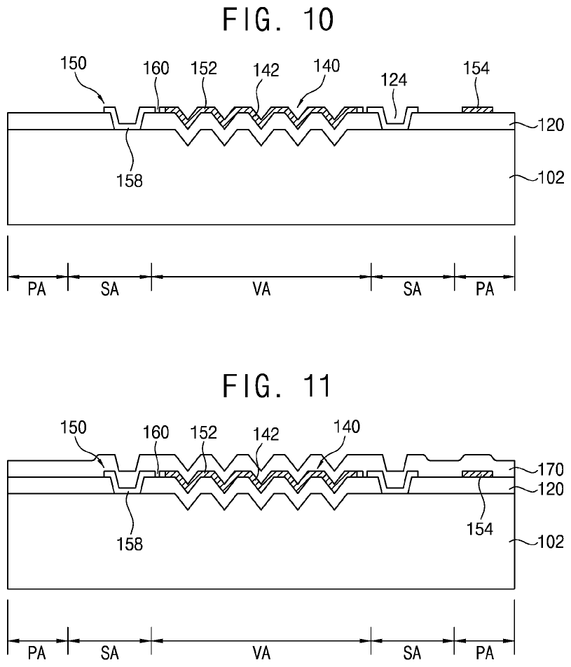

Referring to FIGS. 5 and 10, in step S140, a diaphragm 150 including a lower electrode layer 152 may be formed from the lower silicon layer 130. In embodiments, an ion implantation process may be performed to form a portion of the lower silicon layer 130 into a lower electrode layer 152 having conductivity. Further, a first electrode pad 154 and a first connection pattern 156 (refer to FIG. 1) for connecting the lower electrode layer 152 and the first electrode pad 154 may be formed in the lower silicon layer 130 by the ion implantation process. In particular, a portion of the lower silicon layer 130 in which the convex portions 142 are formed may be formed into the lower electrode layer 152.

Then, the lower silicon layer 130 may be patterned to form a diaphragm 150 including the lower electrode layer 152, the first electrode pad 154, and the first connection pattern 156. In addition, a first anchor portion 158 for fixing the diaphragm 150 on the substrate 102 may be formed on the portion of the substrate 102 exposed by the first anchor channel 124 and a plurality of ventilation holes 160 may be formed between the lower electrode layer 152 and the first anchor portion 158. In embodiments, a photoresist pattern covering portions where the lower electrode layer 152, the first anchor portion 158, the first electrode pad 154, and the first connection pattern 156 are to be formed may be formed on the lower silicon layer 130. Next, an etching process, using the photoresist pattern as an etching mask, may be performed until the lower insulating layer 120 is exposed.

Referring to FIGS. 5 and 11, in step S150, an upper insulating layer 170 may be formed on the lower insulating layer 120 and the diaphragm 150. In embodiments, the upper insulating layer 170 may include silicon oxide and may be formed conformally, that is, to have an approximately uniform thickness by a chemical vapor deposition process.

Referring to FIG. 5, in step S160, an upper electrode layer 182 may be formed on the upper insulating layer 170. In embodiments, as shown in FIG. 12, an upper silicon layer 180 may be conformally formed on the upper insulating layer 170 to have an approximately uniform thickness. In embodiments, the upper silicon layer 180 may be a polysilicon layer formed by a chemical vapor deposition process. Subsequently, an ion implantation process may be performed to form the upper silicon layer 180 into a conductive layer (not shown), that is, a polysilicon layer doped with impurities.

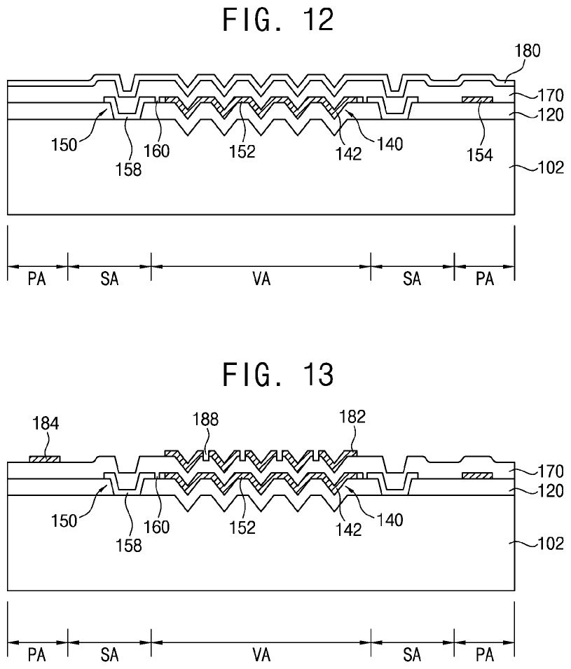

Referring to FIG. 13, the conductive layer may be patterned to form an upper electrode layer 182 corresponding to the lower electrode layer 152, a second electrode pad 184, and a second connection pattern 186 (refer to FIG. 1) for connecting the upper electrode layer 182 and the second electrode pad 184. That is, as shown in FIG. 13, the remaining portions of the conductive layer excluding the upper electrode layer 182, the second electrode pad 184, and the second connection pattern 186 may be removed. In embodiments, a photoresist pattern may be formed on the conductive layer to cover regions where the upper electrode layer 182, the second electrode pad 184, and the second connection pattern 186 are to be formed. Next, an etching process, using the photoresist pattern as an etching mask, may be performed until the upper insulating layer 170 is exposed.

Then, a plurality of holes 188 for forming protrusions 194 (refer to FIG. 2) extending toward the lower electrode layer 152 may be formed by removing portions of the upper electrode layer 182 and the upper insulating layer 170. The holes 188 may have a predetermined depth in order to extend through the upper electrode layer 182 to a portion of the upper insulating layer 170. In embodiments, after forming a photoresist pattern exposing portions where the holes 188 are to be formed on the upper electrode layer 182, an anisotropic etching process using the photoresist pattern as an etching mask may be performed for a predetermined time.

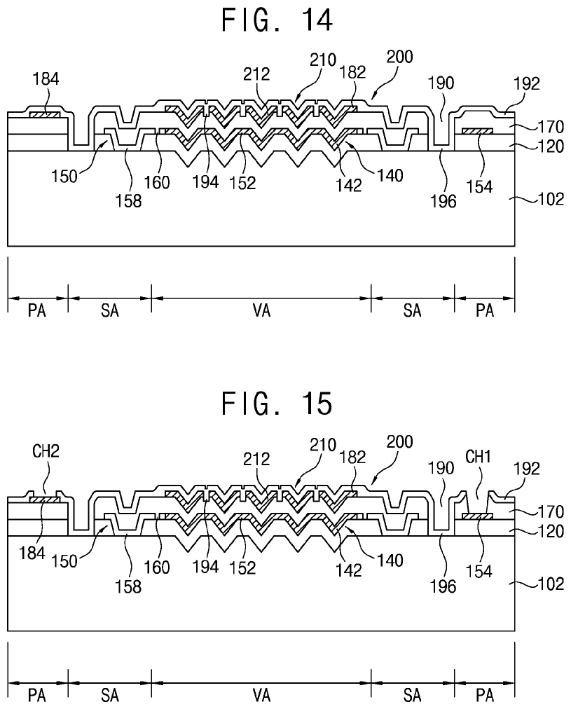

Referring to FIGS. 5 and 14, in step S170, a support layer 192 may be formed on the upper insulating layer 170 and the upper electrode layer 182. In embodiments, the upper insulating layer 170 and the lower insulating layer 120 may be patterned to form a second anchor channel 190 having a circular ring shape surrounding the first anchor portion 158. In embodiments, a photoresist pattern exposing portions where the second anchor channel 190 is to be formed may be formed on the upper insulating layer 170. Next, an anisotropic etching process, using the photoresist pattern as an etching mask, may be performed until the upper surface of the substrate 102 is exposed.

After the second anchor channel 190 is formed, a support layer 192 may be conformally formed on the upper electrode layer 182 and the upper insulating layer 170 to have an approximately uniform thickness. As a result, a back plate 200, including the upper electrode layer 182 and the support layer 192, may be formed above the substrate 102. In this case, the back plate 200 may have a second concave-convex structure 210 corresponding to the concave-convex structure 140 and the second concave-convex structure 210 may include second convex portions 212 corresponding to the convex portions 142. In embodiments, the support layer 192 may be a silicon nitride layer formed by a chemical vapor deposition process. In particular, the support layer 192 may be formed to fill the holes 188, whereby protrusions 194 extending downward from the support layer 192 through the upper electrode layer 182 may be formed. In addition, a portion of the support layer 192 formed in the second anchor channel 190 may be used as a second anchor portion 196 for fixing the support layer 192 on the substrate 102.

Referring to FIG. 5, in step S180, bonding pads 222 and 224 may be formed, which may be electrically connected to the lower electrode layer 152 and the upper electrode layer 182. Specifically, as shown in FIG. 15, a first contact hole (CH1) may be formed by patterning the support layer 192 and the upper insulating layer 170, exposing the first electrode pad 154. In addition, a second contact hole (CH2) may be formed by patterning the support layer 192, exposing the second electrode pad 184. In embodiments, after forming a photoresist pattern exposing portions of the support layer 192 corresponding to the first electrode pad 154 and the second electrode pad 184 on the support layer 192, the first contact hole (CH1) and the second contact hole (CH2) may be formed by an anisotropic etching process using the photoresist pattern as an etching mask.

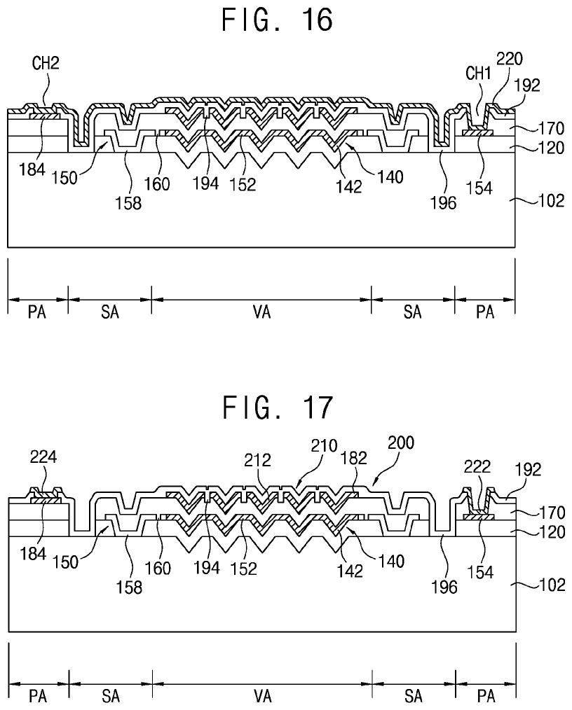

Subsequently, as shown in FIGS. 16 and 17, a first bonding pad 222 and a second bonding pad 224 may be formed on the first electrode pad 154 and the second electrode pad 184, respectively. In embodiments, the first bonding pad 222 and the second bonding pad 224 may be made of a metal such as aluminum and may be formed by forming an aluminum layer 220 on the support layer 192 and then patterning the aluminum layer 220.

After forming the first bonding pad 222 and the second bonding pad 224, as shown in FIG. 18, the support layer 192 and the upper electrode layer 182 may be patterned to form a plurality of air holes 230. In particular, the air holes 230 may be formed through the second convex portions 212 to correspond to the convex portions 142, respectively. In embodiments, after forming a photoresist pattern exposing portions where the air holes 230 are to be formed on the support layer 192, the air holes 230 may be formed by an anisotropic etching process using the photoresist pattern as an etching mask.

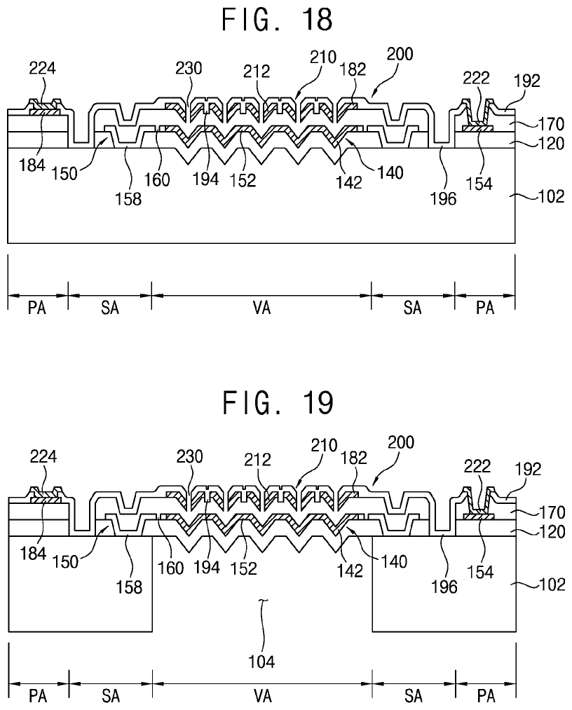

Referring to FIGS. 5 and 19, in step S190, a cavity 104 penetrating through the substrate 102 may be formed. In embodiments, a back grinding process may be performed to reduce the thickness of the substrate 102 and a cavity 104 penetrating the substrate 102 may then be formed. In this case, the cavity 104 may be formed to correspond to the diaphragm 150 and to expose the lower insulating layer 120 by an anisotropic etching process.

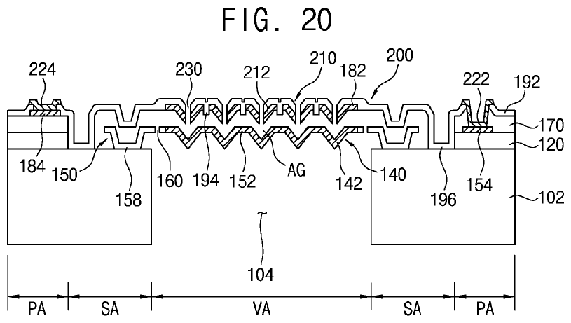

Referring to FIGS. 5 and 20, in step S200, an air gap (AG) may be formed by partially removing the lower insulating layer 120 and the upper insulating layer 170. In embodiments, a portion of the lower insulating layer 120 and a portion of the upper insulating layer 170 formed inside the second anchor portion 196 may be removed by an etching process. In such cases, an etching solution or an etching gas may be supplied between the diaphragm 150 and the back plate 200 through the air holes 230 and the ventilation holes 160. As a result, the diaphragm 150 may be exposed downwardly through the cavity 104 and the air gap (AG) may be formed between the diaphragm 150 and the back plate 200.

In accordance with the embodiments of the present disclosure as described above, the diaphragm 150 and the back plate 200 may include a concave-convex structure 140 and a second concave-convex structure 210 corresponding to each other, respectively. Accordingly, areas facing each other of the diaphragm 150 and the back plate 200 may be increased, and thus, the sensitivity of the MEMS microphone 100 may be significantly improved.

Although the example embodiments of the present disclosure have been described with reference to the specific embodiments, they are not limited thereto. Therefore, it will be readily understood by those skilled in the art that various modifications and changes can be made thereto without departing from the spirit and scope of the present disclosure defined by the appended claims.

What is claimed is:

1. A MEMS microphone comprising:
a substrate having a cavity;
a diaphragm disposed above the substrate to correspond to the cavity; and
a back plate disposed above the diaphragm,
wherein the diaphragm comprises a concave-convex structure.

2. The MEMS microphone of claim 1, wherein the diaphragm comprises a lower electrode layer made of a conductive material and having the concave-convex structure, and
the back plate comprises a support layer made of an insulating material and an upper electrode layer attached to a lower surface of the support layer and made of a conductive material.

3. The MEMS microphone of claim 2, wherein the concave-convex structure comprises convex portions protruding downward.

4. The MEMS microphone of claim 3, wherein each of the convex portions has a shape of a hollow pyramid, a hollow truncated pyramid, a hollow cone, or a hollow truncated cone.

5. The MEMS microphone of claim 2, wherein the diaphragm further comprises a first anchor portion configured to surround the lower electrode layer and to fix the lower electrode layer on the substrate; and
the back plate further comprises a second anchor portion configured to fix the support layer on the substrate.

6. The MEMS microphone of claim 2, wherein the support layer comprises protrusions penetrating through the upper electrode layer and protruding toward the lower electrode layer.

7. The MEMS microphone of claim 1, wherein the back plate comprises a second concave-convex structure corresponding to the concave-convex structure.

8. The MEMS microphone of claim 7, wherein the concave-convex structure comprises convex portions protruding downward, and
the second concave-convex structure comprises second convex portions corresponding to the convex portions and protruding downward.

9. The MEMS microphone of claim 8, wherein each of the convex portions has an upper inclined surface, and
each of the second convex portions has a lower inclined surface corresponding to the upper inclined surface.

10. The MEMS microphone of claim 8, wherein each of the second convex portions has a shape of a hollow pyramid, a hollow truncated pyramid, a hollow cone, or a hollow truncated cone.

11. A method of manufacturing a MEMS microphone, the method comprising:
forming a diaphragm comprising a concave-convex structure above a substrate;
forming a back plate above the diaphragm; and
forming a cavity through the substrate to expose a lower surface of the diaphragm.

12. The method of claim 11, wherein the forming the diaphragm comprises:
forming a mask layer exposing surface portions of the substrate;
forming concave portions by performing an etching process using the mask layer as an etching mask;
removing the mask layer;
forming a lower insulating layer having second concave portions on the substrate;
forming a lower silicon layer having the concave-convex structure on the lower insulating layer; and
forming the diaphragm by patterning the lower silicon layer.

13. The method of claim 12, wherein the forming the diaphragm further comprises:
forming a portion of the lower silicon layer into a lower electrode layer by performing an ion implantation process.

14. The method of claim 12, wherein the forming the diaphragm further comprises:
forming a first anchor channel partially exposing the substrate by partially removing the lower insulating layer,
wherein a portion of the lower silicon layer formed in the first anchor channel functions as a first anchor portion for fixing the diaphragm on the substrate.

15. The method of claim 12, wherein the forming the back plate comprises:
forming an upper insulating layer on the diaphragm;
forming an upper silicon layer on the upper insulating layer;
forming a portion of the upper silicon layer into an upper electrode layer by performing an ion implantation process;
exposing a portion of the upper insulating layer by removing another portion of the upper silicon layer; and
forming a support layer for supporting the upper electrode layer on the upper electrode layer and the exposed portion of the upper insulating layer.

16. The method of claim 15, wherein the forming the back plate further comprises:
forming a second anchor channel partially exposing the substrate by partially removing the upper insulating layer and the lower insulating layer,
wherein a portion of the support layer formed in the second anchor channel functions as a second anchor portion for fixing the back plate on the substrate.

17. The method of claim 15, wherein the forming the back plate further comprises:
forming holes penetrating through the upper electrode layer and removing upper portions of the upper insulating layer,
wherein the support layer is formed to fill the holes, thereby forming protrusions penetrating the upper electrode layer and protruding toward the diaphragm.

18. The method of claim 11, wherein the back plate comprises a second concave-convex structure corresponding to the concave-convex structure.

19. The method of claim 18, wherein the concave-convex structure comprises convex portions protruding downward, and
the second concave-convex structure comprises second convex portions corresponding to the convex portions and protruding downward.

20. The method of claim 19, wherein each of the convex portions has an upper inclined surface, and
each of the second convex portions has a lower inclined surface corresponding to the upper inclined surface.
